(19) United States
(12) Patent Application Publication
(10) Pub. No.: US 2010/0300743 A1
(43) Pub. Date: Dec. 2, 2010

(54) Modified Pillar Design for Improved Flip Chip Packaging

(75) Inventors: Omar J. Bchir, San Diego, CA (US); Lily Zhao, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/476,928

(22) Filed: Jun. 2, 2009

(51) Int. Cl. H05K 1/11; B05D 5/12

(52) U.S. Cl. 174/267; 427/58; 427/123

(57) ABSTRACT

A pillar for flip chip interconnect in an electronic package. The pillar includes an electrically conductive material and a solder wicking inhibitor deposited on the sides of the pillar. The pillar also includes an exposed face for contacting the electrically conductive material and solder material on the substrate. In another embodiment, a method of forming a pillar composed of an electrically conductive material which inhibits solder wicking is provided. The method includes coating the pillar with a solder wicking inhibitor and polishing a face of the pillar to expose the underlying electrically conductive material.

### FIELD OF DISCLOSURE

This disclosure relates generally to a flip chip package, and in particular to a flip chip package having a pillar with a solder wicking inhibitor for flip chip interconnect.

### BACKGROUND

In electronic packaging, a flip chip can include a pillar that extends from a contact on a die or wafer to a solder connection on a substrate. The solder connection, for example, can be a solder on pad (SOP) connection. The pillar can be substantially cylindrical and forms an electrically conductive interconnect with the substrate through the SOP. A conventional pillar is metallic and does not include any external coating or layer.

When the pillar is coupled to the solder material, the solder material can wick along the sides of the pillar. It can be difficult to control the degree of wicking along the sides of the pillar because each side of the pillar comprises metallic material. In some instances, the solder material can wick so far along the sides of the pillar that the die is pulled closer to the substrate such that the solder joint gap height between the die and substrate is substantially reduced. A reduced solder joint gap height can be problematic and cause underfill flow problems. After chip attachment, for example, an underfill epoxy is injected between the die and substrate, but a reduced gap height makes it more difficult to inject the epoxy. This condition can cause problems with the assembly process and reduce the reliability of the package.

In more extreme instances, all of the solder material from the SOP can wick along the sides of the pillar such that the solder is removed from the substrate. In these instances, a non-connect open in the solder joint is created that can render the package inoperable.

Therefore, it would be desirable to optimize the flip chip design of an electronic package by providing a pillar with a solder wicking inhibitor that improves the manufacturability of the flip chip package and reduces the degree of wicking of the solder material along the sides of the pillar.

### SUMMARY

For a more complete understanding of the present disclosure, reference is now made to the following detailed description and the accompanying drawings. In an exemplary embodiment, a pillar for a flip chip interconnect is provided. The pillar includes an electrically conductive material. A solder wicking inhibitor can be deposited on the sides of the pillar such that the pillar includes an exposed face for contacting the electrically conductive material and solder material. The pillar can be copper, gold, or silver, whereas the solder wicking inhibitor can include an oxide of a metal such as chromium, nickel, or palladium. Alternatively, the solder wicking inhibitor can be a polymer formed from an epoxy-based material.

In another embodiment, a method of forming a pillar composed of an electrically conductive material which inhibits solder wicking is provided. The method includes coating the pillar with a solder wicking inhibitor and polishing a face of the pillar to expose the underlying electrically conductive material. The polishing step can be a chemical-mechanical process or a mechanical process. The solder wicking inhibitor can be a polymer formed from an epoxy-based material or a metal oxide formed from chromium, nickel, or palladium.

Coating the pillar with the solder wicking inhibitor can include depositing a metal layer on the pillar and oxidizing the metal layer. Depositing the metal layer can be achieved by autocatalytic (electroless) metal deposition or immersion plating. Alternatively, when the solder wicking inhibitor is a polymer, the coating step can be a spin-on process, a spray process, or dipping process.

In a different embodiment, a flip chip interconnect in an electronic package is provided. The flip chip interconnect includes means for coupling a die to a substrate and means for inhibiting solder wicking along the sides of the means for coupling. The means for coupling can include an exposed surface of electrically conductive material for contacting with solder material at the substrate. The means for inhibiting solder wicking can comprise a metal oxide or polymer.

### BRIEF DESCRIPTION OF THE DRAWINGS

FIG. 1 is a schematic view of a conventional flip chip package prior to attachment;

FIG. 2 is a schematic view of the conventional flip chip package of FIG. 1 after attachment without wicking;

FIG. 3 is a schematic view of the conventional flip chip package of FIG. 1 after attachment with wicking;

FIG. 4 is a schematic view of the conventional flip chip package of FIG. 1 after attachment with severe wicking;

FIG. 5 is a schematic view of an exemplary embodiment of an improved flip chip package;

FIG. 6 is a schematic view of a die with a pillar;

FIG. 7 is a schematic view of the pillar of FIG. 6 plated with a metal layer;

FIG. 8 is a schematic view of the pillar of FIG. 7 oxidized with a solder wicking inhibitor;

FIG. 9 is a schematic view of the pillar of FIG. 8 polished to expose a pillar surface;

FIG. 10 is a schematic view of the pillar of FIG. 9 for attaching to a substrate;

FIG. 11 is a schematic view of a flip chip package without wicking; and

FIG. 12 is a block diagram showing an exemplary wireless communication system in which a package substrate with a plurality of metal elements may be advantageously employed.

### DETAILED DESCRIPTION

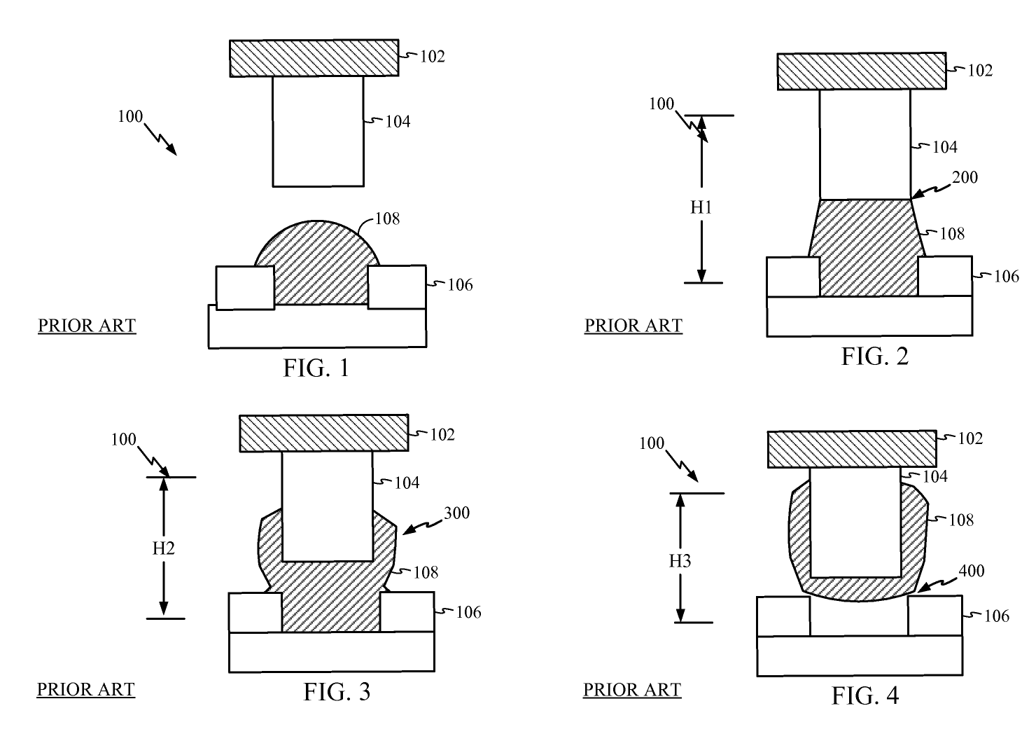

Referring to the exemplary embodiment shown in FIG. 1, a conventional flip chip package design is provided. The flip chip package 100 includes a die or wafer 102 from which a pillar 104 extends. The flip chip package 100 is complete when the die or wafer 102 is coupled to a substrate 106. A solder bump 108 is disposed on the substrate 106 for coupling to the pillar 104. In FIG. 2, for example, the solder material 108 couples to the pillar 104 and forms a conductive interconnect 200. The conductive interconnect 200 can also be referred to as a flip chip interconnect. While there is only one conductive interconnect 200 shown in FIG. 2, there can be multiple conductive interconnections between pillars 104 and solder bumps 108.

The pillar 104 includes electrically conductive material and is free of any external coating or layer. An electrical connection can be made between the pillar 104 and substrate 106 when the solder material 108 wets to the pillar 104. In FIG. 2, the flip chip interconnect 200 is such that the solder material 108 does not wick along the sides of the pillar 104. In this case, a desired solder joint gap height H1 is maintained. However, it can be difficult to control the gap height H1 in conventional flip chip package designs because the solder material 108 tends to wick along the sides of the pillar 104. In FIG. 3, for example, the solder material 108 is shown wicking along the sides of the pillar 104. The wicking solder 300 can cause the die or wafer 102 to be pulled closer to the substrate 106 which reduces the overall gap height H2. The gap height H2 in FIG. 3 is less than the gap height H1 of FIG. 2. In extreme cases, such as the one depicted in FIG. 4, the solder material 108 severely wicks along the sides of the pillar 104 and can leave a non-contact open in the solder joint of the substrate 106. Such cases are likely to present a performance and reliability risk. The gap height H3 of FIG. 4 is also less than the gap height H1 of FIG. 2, and in some instances, gap height H3 is less than gap height H2 of FIG. 3.

Controlling the degree of solder wicking is important to both the assembly and overall performance of the package. After the flip chip is attached, an electrically-insulating epoxy is “underfilled” or injected into the area that forms the gap (e.g., between the chip and substrate). The epoxy can provide a stronger mechanical connection between the chip and substrate, a heat bridge, and ensure the solder joints are not overly stressed due to the coefficient of thermal expansion (CTE) mismatch between the chip and substrate. When the gap height is reduced, however, it can be more difficult to underfill the epoxy into the area between the chip and substrate. These conditions can create risks in reliability and assembly of the package.

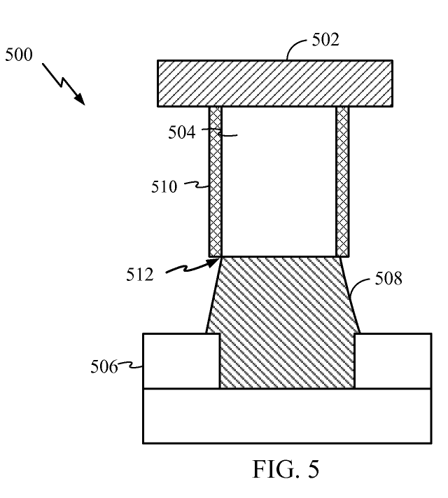

To overcome these disadvantages of conventional flip chip designs, an exemplary embodiment of an improved flip chip package is shown in FIG. 5. The flip chip package 500 includes a die 502 from which a pillar 504 extends. Although only one pillar 504 is shown in FIG. 5, there can be numerous pillars extending from the die 502 in other embodiments. The pillar 504 can be cylindrical or any other shape known to the skilled artisan. In addition, the pillar 504 can be made from copper, gold, or silver. Copper may be used in some instances because it is cheaper and has better electromigration resistance than gold or silver. In other instances, silver may be used due to its better electrical resistivity compared to copper or gold.

The pillar 504 can couple to a substrate 506 through a solder connection. A solder on pad (SOP) interconnection is formed when the pillar 504 couples to solder material 508 provided on the substrate 506. As the pillar 504 contacts the solder material 508, a conductive interconnection 512 is formed. The solder material 508 is prevented from wicking along the sides of the pillar 504, however, due to a solder wicking inhibitor 510 which is coated on the sides of the pillar 504. The solder wicking inhibitor 510 can be a metal oxide coating formed from chromium, nickel, palladium or other metal. Alternatively, the solder wicking inhibitor 510 can be a polymer, such as an epoxy-based material. The solder wicking inhibitor 510 allows for controlling the solder joint gap height more effectively and thus can improve the flip chip assembly and reliability. Also, in those embodiments in which numerous pillars extend from the die or wafer 502, there likewise can be numerous conductive interconnections 512 formed between the die or wafer 502 and the substrate 506.

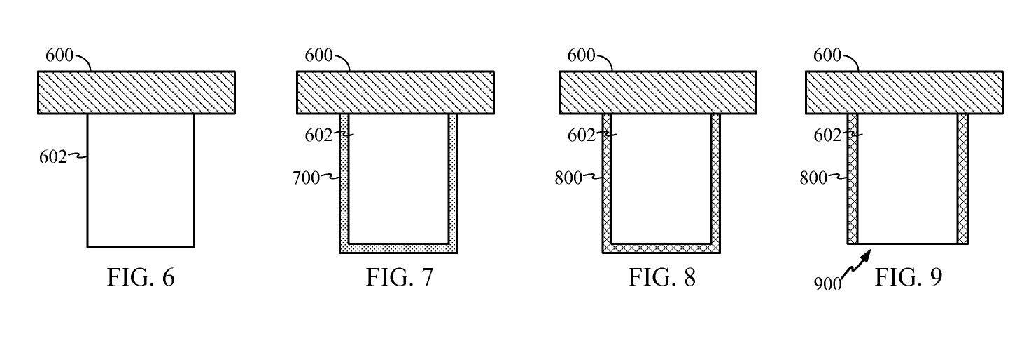

In another embodiment, a method of forming a pillar composed of an electrically conductive material which inhibits solder wicking is also provided. With reference to FIG. 6, a die or wafer 600 of a chip is provided with a pillar 602 extending from the die or wafer 600. The pillar 602 can have a cylindrical cross-section or any other known cross-section. Further, the pillar 602 can be made of an electrically conductive material such as copper. Alternatively, the pillar 602 can be made of silver or gold. The die or wafer 600 can be made, for example, from silicon or other similar material.

To prepare the pillar 602 such that it resists solder wicking, the pillar 602 can undergo an electroless metal plating process. In FIG. 7, for example, the pillar 602 is coated with a layer of electroless metal 700 such as nickel, chromium, or palladium which have metal-oxide counterparts that are more stable than copper-oxide. In addition, these metals can be plated or coated to the pillar 602 by commercially available electroless plating bath chemistries. However, other known electroless metals can be used as well. Applying the layer of electroless metal 700 to the pillar 602 can be achieved by an electroless metal deposition or immersion plating process. In a non-limiting embodiment, the layer thickness of the electroless metal 700 is less than 5 μm.

The metals may need a catalyst such as palladium (Pd) in order to deposit or plate onto the pillar 602. The catalyst should adhere to the pillar 602, but not to the die or die passivation layer. As such, the electroless metal 700 will only plate onto the pillar. Once the electroless metal 700 is deposited or plated onto the pillar 602, the method can further include removing the die or wafer 600 from the plating bath and exposing the metal-coated pillar 602 to an oxidizing ambient (air, steam, wet chemical bath, etc.) to oxidize the metal coating 700. With reference to FIG. 8, a metal oxide layer 800 coats the outside surfaces of the pillar 602.

In another non-limiting embodiment in which the pillar 602 is made of copper, electroless chromium can be used to form CrOₓ-type oxides such as CrO₂, Cr₂O₃, or Cr₃O₄. Alternatively, when nickel is coated to the copper pillar as an electroless metal, NiOₓ-type oxides such as Ni₂O₃ can form on the external surfaces of the copper pillar 602. Likewise, when palladium is used as the electroless metal, PdOₓ-type oxides can be coated on the external surfaces of the copper pillar.

Once the pillar 602 is coated with the metal oxide layer 800, a surface or face 900 of the pillar 602 is exposed by a polishing process. In FIG. 9, for example, a chemical-mechanical polishing (CMP) process can be performed on the pillar 602 to expose a surface or face 900. The exposed surface or face 900 can then be used, for example, as a solderable surface for contacting solder material disposed on a substrate.

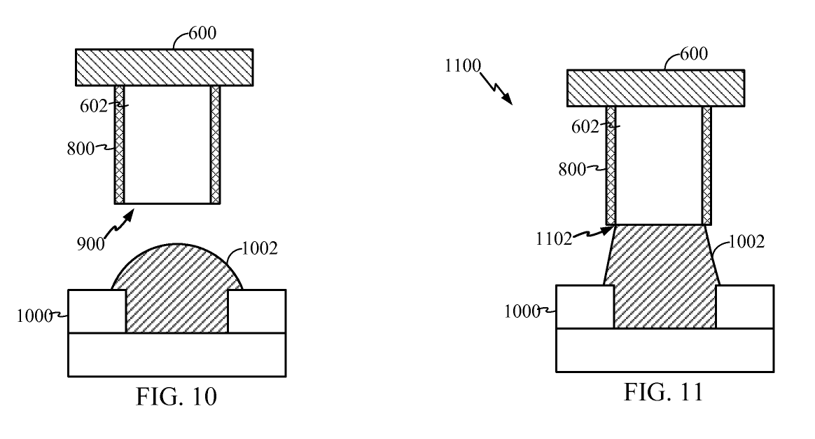

In FIG. 10, the exposed surface or face 900 of the pillar 602 is oriented to face solder material 1002 provided on a SOP-based substrate 1000. As the flip chip is attached to the SOP-based substrate in FIG. 11, the exposed surface or face 900 of the pillar 602 couples with the solder material 1002 to form a conductive interconnect 1102. The metal oxide layer 800 acts as a solder wicking inhibitor that resists the solder material 1002 wicking along the sides of the pillar 602. As a result, a desired gap height can be controlled more easily and better underfill flow capability and reproducibility can be achieved. In one embodiment, the desired gap height may be approximately 70 μm or less. In other embodiments, the desired gap height may be greater than 70 μm. Although FIGS. 6-11 illustrate only one pillar 602 being coupled to solder material 1002, there can be a plurality of pillars 602 extending from the die or wafer 600 and being coated with a solder wicking inhibitor. The plurality of pillars 602 can be coupled to the substrate 1000 to form a plurality of conductive interconnections 1102.

In an alternative embodiment, the die or wafer 600 and pillar 602 may be coated with a polymer rather than an electroless metal. The polymer can be an epoxy-based material that is applied to the pillar via a spin-on process, spray process, or dipping process. Other methods of applying the polymer to the pillar known to the skilled artisan may be used as well. Once the polymer is applied to the pillar 602, an exposed surface or face can be achieved by mechanically polishing a surface or face of the pillar 602. One such mechanical process that can be used for polishing a surface or face of the pillar 602 is mechanical grinding, although other mechanical processes known to one skilled in the art can be used as well. In this embodiment, the polymer is the solder wicking inhibitor and as the flip chip attaches to the SOP-based substrate, the polymer resists the solder material from wicking along the sides of the pillar.

After the solder wicking inhibitor has been coated on the pillar and the flip chip package is completed, the electrical package can be made ready for installation in an electronic device such as a cell phone, computer, personal digital assistant (PDA), and the like.

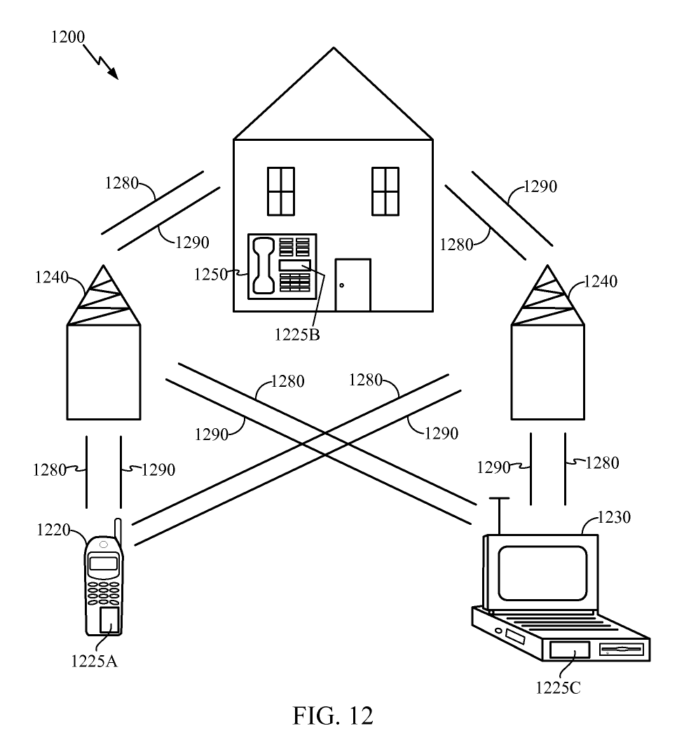

FIG. 12 shows an exemplary wireless communication system 1200 in which an embodiment of an electronic package with an improved flip chip interconnect may be advantageously employed. For purposes of illustration, FIG. 12 shows three remote units 1220, 1230, and 1250 and two base stations 1240. It should be recognized that typical wireless communication systems may have many more remote units and base stations. Any of remote units 1220, 1230, and 1250, as well as the base stations 1240, may include an electronic package with an improved flip chip interconnect such as disclosed herein. FIG. 12 shows forward link signals 1280 from the base stations 1240 and the remote units 1220, 1230, and 1250 and reverse link signals 1290 from the remote units 1220, 1230, and 1250 to base stations 1240.

In FIG. 12, remote unit 1220 is shown as a mobile telephone, remote unit 1230 is shown as a portable computer, and remote unit 1250 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 12 illustrates certain exemplary remote units that may include an electronic package with an improved flip chip interconnect as disclosed herein, the package is not limited to these exemplary illustrated units. Embodiments may be suitably employed in any electronic device in which an electronic package with an improved flip chip interconnect is desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A pillar for flip chip interconnect, comprising:
a body composed of an electrically conductive material, the body including an exposed surface for coupling the electrically conductive material and a solder material; and
a solder wicking inhibitor deposited on the sides of the body, wherein the solder wicking inhibitor resists wicking of the solder material along the sides of the body.

2. The pillar of claim 1, wherein the electrically conductive material comprises copper, gold, or silver.

3. The pillar of claim 1, wherein the solder wicking inhibitor comprises a metal oxide.

4. The pillar of claim 3, wherein the metal oxide comprises an oxide of chromium, nickel, or palladium.

5. The pillar of claim 1, wherein the solder wicking inhibitor is a polymer.

6. The pillar of claim 5, wherein the polymer comprises an epoxy-based material.

7. A method of forming a wicking resistant, electrically conductive pillar, comprising:
fabricating a pillar composed of an electrically conductive material;
coating the pillar with a solder wicking inhibitor; and
polishing a face of the pillar to expose the underlying electrically conductive material.

8. The method of claim 7, wherein the polishing a face of the pillar comprises a chemical-mechanical process.

9. The method of claim 7, wherein the polishing a face of the pillar comprises a mechanical process.

10. The method of claim 7, wherein the coating the pillar comprises depositing a metal layer on the pillar.

11. The method of claim 10, wherein the coating the pillar comprises oxidizing the metal layer.

12. The method of claim 10, wherein the depositing a metal layer comprises electroless metal deposition.

13. The method of claim 10, wherein the depositing a metal layer comprises immersion plating.

14. The method of claim 7, wherein the coating the pillar comprises a spin-on process.

15. The method of claim 7, wherein the coating the pillar comprises a spray process.

16. The method of claim 7, wherein the coating the pillar comprises a dipping process.

17. A flip chip interconnect in an electronic package, comprising:
means for coupling a die to a substrate; and
means for inhibiting solder wicking along the sides of the means for coupling;
wherein, the means for coupling includes an exposed surface of electrically conductive material for contacting with solder material coupled to the substrate.

18. The flip chip interconnect of claim 17, wherein the means for inhibiting solder wicking comprises a polymer.

19. The flip chip interconnect of claim 17, wherein the means of inhibiting solder wicking comprises a metal oxide.

20. The flip chip interconnect of claim 19, wherein the means for coupling comprises copper, gold, or silver.
